(19) United States
(12) Patent Application Publication
(10) Pub. No.: US 2008/0153265 A1
(43) Pub. Date: Jun. 26, 2008

(54) Semiconductor Device Manufactured Using an Etch to Separate Wafer into Dies and Increase Device Space on a Wafer

(75) Inventor: Kevin P. Lyne, Fairview, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/614,369

(22) Filed: Dec. 21, 2006

(51) Int. Cl. H01L 21/00

(52) U.S. Cl. 438/465

(57) ABSTRACT

In one aspect, the method comprises etching a trench into a scribe street located between dies formed on a semiconductor wafer. The dies each have circuitry, and the etching is conducted to a depth within the semiconductor wafer that extends beyond a depth of the circuitry. The etch forms an edge of the die. A passivation layer is placed on the edge of the die. A back surface of the semiconductor wafer is removed until it intersects the trench, which separates the dies from the wafer. The removing process does not remove the passivation layer from the edge of the die.

### TECHNICAL FIELD

The following disclosure discusses, in general, a semiconductor device and manufacture of that device and, in one embodiment, discusses a semiconductor device and a method of manufacture therefore that uses an etch to separate dies from a semiconductor wafer and forms a passivation layer on the edges of each of the dies to increase device space on a wafer.

### BACKGROUND

Transistor device size continues to decrease as semiconductor device manufacturers drive to realize higher transistor density, lower power consumption, and higher speed operation of integrated circuits. As transistor device size decreases, some transistor manufacturing steps must be modified to reflect the smaller physical dimensions of the scaled transistors. Moreover, there is an emphasis in the semiconductor industry to increase the amount of wafer space available so that the component density may be increased further, while adequately protecting the circuitry.

Scribe seals and scribe streets are areas that presently consume much needed wafer space. Scribe seals are placed at the perimeter of each of the dies to protect the outer edges of the circuitry from postproduction processes. The scribe seals are typically formed during the fabrication of transistor devices and during the filling of the vias and the formation of the metal layers. As such, they consist of the same materials used to form the vias and metal layers. They are built next to the scribe streets on opposing sides of the circuitry and within the silicon wafer, and the transistor's circuitry typically extends to the scribe seals. The scribe streets are the areas located between dies that are set aside for physically separating the dies from the semiconductor wafer.

When complete, the scribe seals help passivate and protect the circuitry during the dicing or sawing processes that are presently used to physically separate the die. Unfortunately, however, each of the scribe seals and scribe streets requires a relatively large amount of wafer surface. For example, in a wafer having a die size of 2000 microns square, the scribe street may be about 62 microns wide with the scribe seals also consuming about 10 microns on each side of the circuitry. Thus, the percentage of scribe street/scribe area may consume as much as 8.4% of the wafer.

As mentioned above, manufacturers typically use saw blades to separate the dies from the wafer. Conventional processes typically use varying blade thicknesses and depths to dice the wafer into the individual dies. Although great care is used, damage can still occur to the circuitry. This is due primarily to the fact that many semiconductor devices include several layers of brittle dielectric material having low dielectric constants, which makes the structure delicate and susceptible to physical damage. Thus, during the heavy mechanical cutting action of the saw blade, damage can easily occur to the delicate circuit structures. In addition, the ragged edge left by the saw blade can form conductive paths along the die's edge, which in turn, can lead to shorts within the circuitry or may be a place into which moisture can enter the device.

Accordingly, what is needed in the art is a device and method for making that device that avoids the problems associated with the above-discussed conventional processes.

### SUMMARY

In one embodiment, the method comprises etching a trench into a scribe street located between dies that are formed on a semiconductor wafer. The dies each include circuitry, and the etch is conducted to a depth within the semiconductor wafer that extends beyond a depth of the circuitry and forms an edge of the die. A passivation layer is placed on the edge of the die and a back surface of the semiconductor wafer is removed until it intersects the trench, which separates the dies from the wafer.

In another embodiment, a method of manufacturing a semiconductor device comprises forming active circuitry within dies located on a semiconductor wafer. A scribe street is located between each of the dies, and the active circuitry terminates at the scribe street. A trench is etched into each of the scribe streets to a depth that extends beyond a depth of the active circuitry. In this embodiment, the etch leaves a portion of the scribe street between the trench and the active circuitry and forms an edge of the die. Also, a scribe seal is not present between the edge of the die and the active circuitry. A passivation layer is formed on the edge of the die such that the passivation layer extends past the depth of the active circuitry. A back surface of the semiconductor wafer is removed until the trench is intersected. This intersection separates the dies from the semiconductor wafer, but the passivation layer remains on the edge of each of the dies.

Another embodiment provides a semiconductor device. The device comprises a die that has an etched edge that includes a portion of a scribe street. Active circuitry is located on the die and dielectric layers are located over the active circuitry. Interconnects that are located within and over the dielectric layers contact the active circuitry. The active circuitry, dielectric layers, and interconnects form at least a portion of an integrated circuit (IC) and the IC terminates at the edge of the die. A passivation layer is located on the portion of the scribe street that forms the edge of the die and a scribe seal is not present between the edge of the die and the active circuitry.

### BRIEF DESCRIPTION OF THE DRAWINGS

For a better understanding, reference is now made to the following descriptions taken in conjunction with the accompanying drawings, in which:

FIG. 1 illustrates a partial view of a semiconductor wafer having dies located thereon;

FIGS. 2-4 illustrate certain manufacturing steps of a semiconductor device where a trench and passivation layer are formed;

FIGS. 5-6 illustrate embodiments where the passivation layer is located over an overcoat layer;

FIG. 7 illustrates an embodiment subsequent to the partial removal of a back surface of the semiconductor wafer; and

FIG. 8 illustrates an IC manufactured by one embodiment described herein.

### DETAILED DESCRIPTION

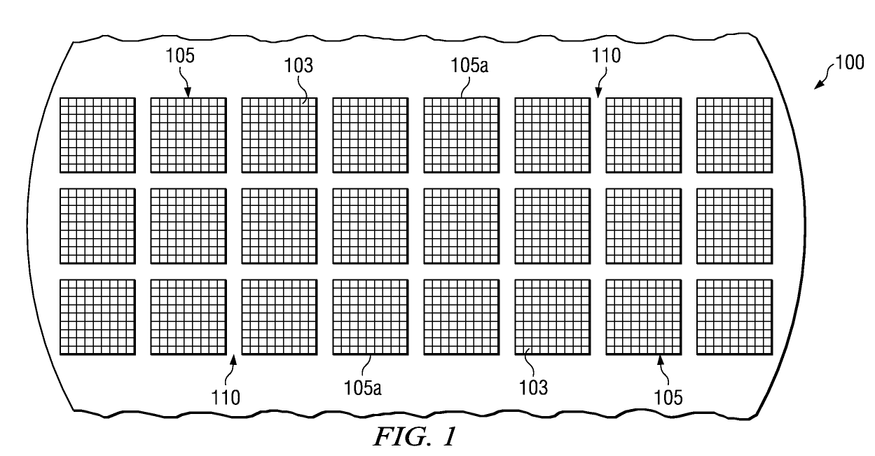

FIG. 1 illustrates a partial view of a semiconductor wafer 100 that has multiple dies 105 located thereon that contain circuitry 103 within their perimeters 105a. It should be noted that, unless otherwise stated, conventional processes and materials may be used to construct the various embodiments. The circuitry 103 may comprise integrated circuits (ICs) that can include devices, such as active circuitry (e.g., transistors), interconnects, and overlying dielectric layers, or it may include any other microelectronic device or circuitry that can be formed on a semiconductive wafer. It should be understood that the circuitry 103 also includes any dielectric structures, such as isolation trenches or field oxides, etc. that may be located at the outer edge of the electrically active circuitry and provides electrical isolation or structural support. The semiconductor wafer 100 may be any type of semiconductor material known to those skilled in the art.

Scribe streets 110 separate the dies 105. The streets 110 do not form a portion of the circuitry 103 and their purpose is to provide a space on the wafer so that the dies can be separated from the wafer 100. As mentioned above, conventional semiconductor wafers include scribe seals that are metal structures, which abut the scribe street 110 and are located between the circuitry 103 and the scribe street 110. However, these conventional scribe seals are not necessarily present in all embodiments. Thus, since the scribe seals may be omitted, additional wafer space can be realized.

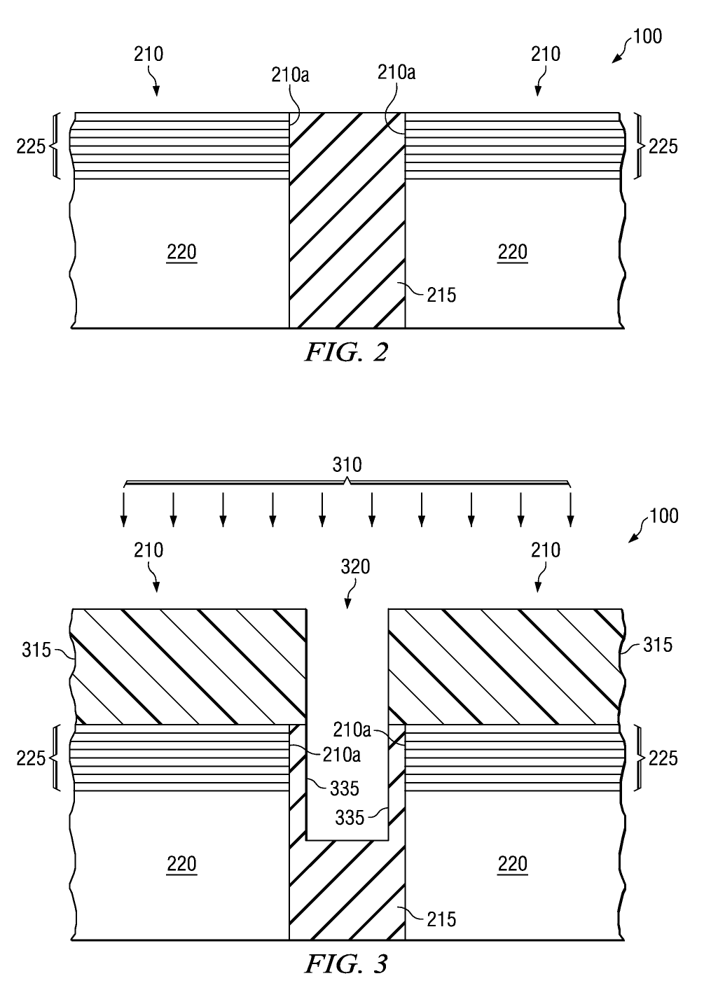

FIG. 2 is an enlarged view of the semiconductor wafer 100 of FIG. 1 that shows adjacent dies 210. A scribe street 215 is located between and separates the dies 210. In this embodiment, scribe seals are omitted, and the scribe streets 215 may have a reduced width due to the processes and devices discussed herein. For example, in conventional devices, the scribe streets may be 62 microns wide or wider, but with certain embodiments, the scribe street's 215 width may be reduced to as little as 10 microns to provide additional devices on the same wafer 100. Additional space savings may be realized by eliminating scribe seals that are present in conventional processes, as shown in FIG. 2. In other embodiments, however, the scribe seals may be present or their widths may be reduced from conventional designs to achieve additional space savings.

The semiconductor wafer 100 further includes a semiconductor substrate 220, which may be comprised of any conventional material, e.g., silicon, germanium, or silicon germanium, etc. Circuitry 225, which may be the same or different from die to die, is located over the substrate and within the perimeter 210a of each of the dies 210. The circuitry 225, illustrated as striations within each die 210, may comprise a device level with gate electrodes, typically located at the bottom level, and any number of metal levels located thereover. In FIG. 2, a conventional scribe seal is not present, and the circuitry 225 terminates at or abuts the street 215. As mentioned above, the termination point or end of circuitry 225 may include any isolation structure or structures that extend laterally past the active devices of the circuitry 225 and to street 215. In such embodiments, an isolation structure, such as a trench or field oxide structure may be located between the active devices and the street 215. The outer edges of the generic striations of circuitry 225 may, therefore, include such structures.

In FIG. 3, the semiconductor wafer 100 is subjected to an etch process 310 following the deposition and patterning of a resist layer 315. The resist protects the circuitry 225 from the effects of the etch 310. The etch 310 may include any method that is capable of forming a small trench in the street 215. For example, in one embodiment, the etch 310 may be a conventional wet etch, or in another embodiment, the etch process 310 may be a plasma etch. In yet another embodiment, the etch 310 may involve the use of a high energy beam, such as a laser. Those skilled in the art understand that the process parameters for the etch 310 in those embodiments that involve a wet etch or plasma etch will depend on the composition of the street 215 and the type of etch that is used.

The etch 310 is conducted to form a trench 320 in the street 215. The depth of the trench may vary, but the trench should extend past the depth or lowest level of the circuitry 225. The depth or lowest level of the circuitry 225 may include the interface between an epitaxial layer and the base substrate 220. It may also include any buried contacts, isolation regions, or other structures that are involved in the operation of the circuitry 225, either as conductors or electrical insulators, and that are located below the gate electrodes or well regions of the circuitry 225.

The width to depth aspect ratio of the trench 320 may also vary, but in one embodiment, the aspect ratio may range from about 1:8 to about 1:10. The width of the trench 320 may also vary, but the width must be sufficient to allow room for the deposition of a passivation layer within the trench 320. For example, the width may be about 4 microns. In the embodiment illustrated in FIG. 3, the resist 315 is patterned to expose only a portion of the street 215 to the etch 310. Thus, upon completion of the etch 310, a portion of the street 215 is located between the trench 320 and the circuitry 225. However, in other embodiments, the resist 315 may be patterned to expose the entire width of the street 215. In such cases, the width of the trench 320 may be as wide as the street 215 and all portions of the street 215 would be removed. In such cases, the aspect ratio may extend beyond the range discussed above. In either embodiment, the etch 310 forms an edge 335 for each of the respective dies 210.

After the trench 320 is formed, a passivation layer 410 is deposited in the trench 320, as seen in FIG. 4. The passivation layer 410 should coat the walls of the trench 320 to at least a point that extends below the depth of the circuitry 225. The passivation layer 410 may be blanket deposited over the entire wafer 100, as shown, and in this embodiment, the passivation layer 410 also serves as a protective overcoat. In one alternative embodiment, the wafer 100 may be masked and patterned with a resist to form an opening over the trench 320; the passivation layer 410 may then be deposited through the opening and within the trench 320 and on the resist. In this embodiment, bonds pads, which are not shown, could be formed subsequent to the deposition of the passivation layer 410 and may be formed before or after the trench 320 is formed. Conventional materials and processes may be used to form the passivation layer 410. For example, in one embodiment, the passivation layer 410 may comprise silicon nitride, silicon oxygen nitride or combinations thereof.

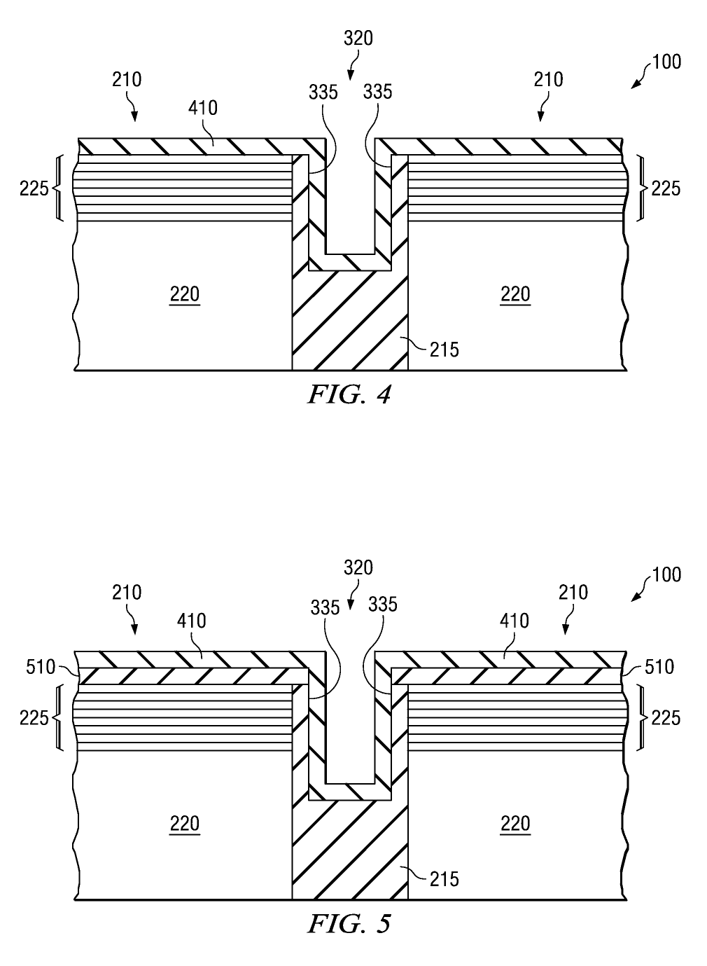

FIG. 5 illustrates another embodiment. In this embodiment, the passivation layer 410 is deposited over a protective overcoat layer 510. The overcoat layer 510 may be a conventional protective overcoat layer that is deposited to generally protect and seal the circuitry 225 environmental conditions as much as possible. When present, the overcoat layer 510 is first blanket deposited over the wafer 100. The above discussed etch, which also removes a portion of the overcoat layer 510 located over the street 215, is then conducted to form the trench 320. Subsequently, the passivation layer 410 is deposited over the overcoat layer 510 and in the trench 320, as shown. In this embodiment, bond pads, which are not shown, may be formed prior or subsequent to the deposition of the passivation layer 410. Those skilled in the art would understand how to alter the various process steps to form the bond pads given the teachings herein.

FIG. 6 illustrates another embodiment of the semiconductor wafer 100 where the passivation layer 410 is patterned in a way that the passivation layer 410 just overlaps the overcoat layer 510 at its edges. In such instances, the passivation layer 410 and the overcoat layer 510 together form a seal for the circuitry 225; that is, it forms an environmental seal that inhibits moisture and contaminates from entering the circuitry 225.

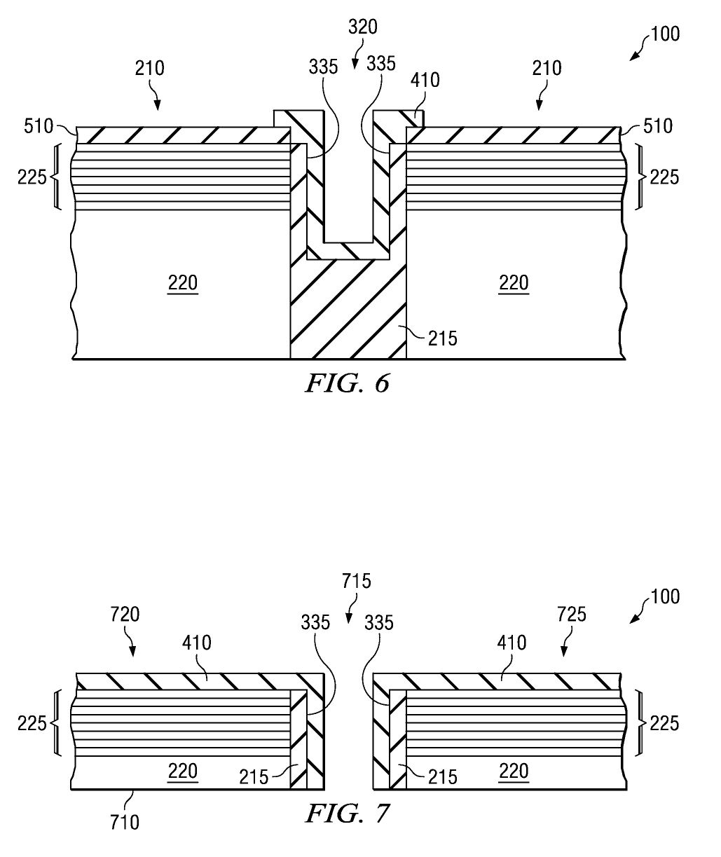

Following the formation of the passivation layer 410 and the completion of the bond pad formation, a back surface 710 (non-circuit side) of the wafer 100 is subjected to a back-grind or a chemical/mechanical polishing (CMP) process. The back-grind or CMP process, which may be conventional, is conducted until the trench is intersected. At this point, the trench no longer exists, and is replaced by a separation space 715. When the back-grind reaches the trench the dies 720 and 725 are separated from the wafer 100 and from each other to form the individual dies 720 and 725, as seen in FIG. 7. A conventional adhesive sheet, which is not shown, may be applied to the circuit side of the semiconductor wafer 100. The adhesive sheet holds the separated dies 720 and 725 together during and after the back-grind or CMP process. The adhesive sheet has glue that looses its adhesive qualities when subjected to ultra-violet (UV) light. Once the back surface 710 no longer connects the dies 720 and 725 together, the adhesive sheet is subjected to UV light, which allows the individual dies 720 and 725 to be easily removed from the adhesive sheet.

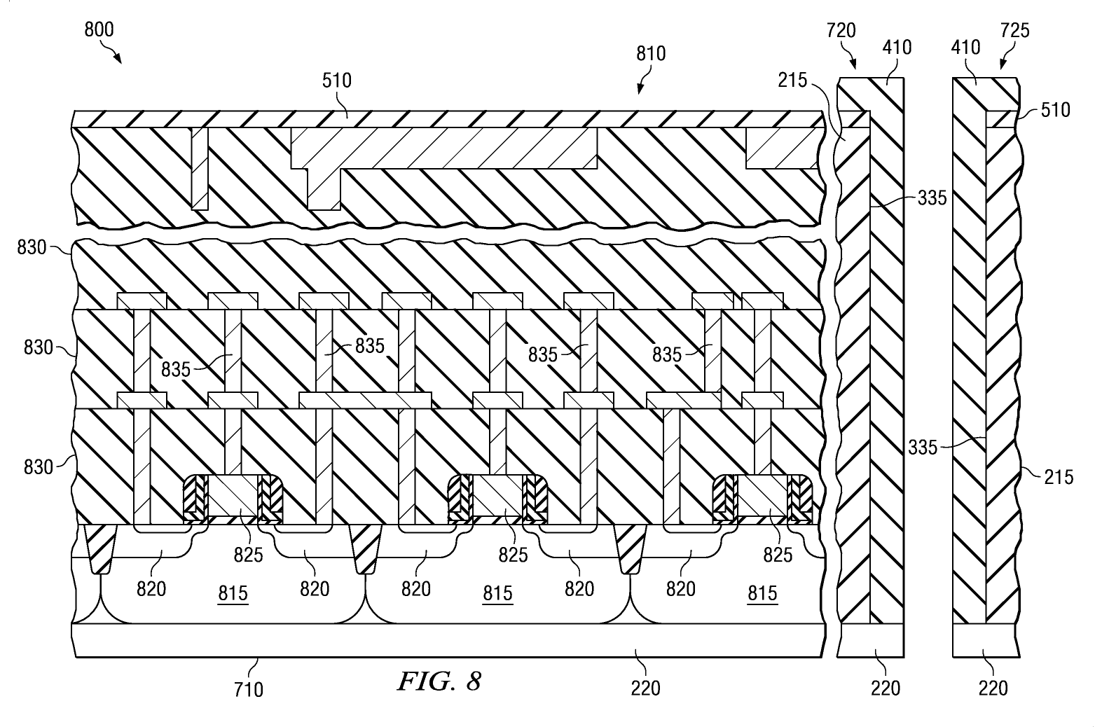

FIG. 8 shows semiconductor dies 720 and 725 (not to scale) wherein at least dies 720 includes circuitry 810 that is configured as an IC. The IC circuitry 810 may be of conventional design. In one embodiment, the circuitry 810 may include conventional structures such as wells 815, source/drains 820, gate electrodes 825, dielectric layers 830, and interconnects 835 formed in and over the dielectric layers. 830. The die 800 further includes the components discussed above regarding the various embodiments, and therefore, are designated the same. In this embodiment, the scribe seal is not present and the circuitry 810, including any outer isolation structures, terminates or ends at the scribe street 215, as explained above.

From the foregoing, embodiments of a method and device that saves additional space across a semiconductor wafer are presented. Conventional scribe seals can be eliminated, if desired, and the scribe street's width can be reduced. This additional space is gained by using an etch to form a trench after a passivation layer is deposited in the trench. A back-grind or CMP process is used to remove semiconductor material from the back surface of the wafer until it intersects the trench and separates the dies into individual dies. The passivation layer remains in place following the back-grind process and forms at least a portion of an environmental seal.

Those skilled in the art will appreciate that other and further additions, deletions, substitutions and modifications may be made to the described embodiments without departing from the scope of the invention.

What is claimed is:

1. A method of manufacturing a semiconductor device, comprising:
Etching a trench into a scribe street located between dies formed on a semiconductor wafer, the dies each including circuitry, and wherein the etching is conducted to a depth within the semiconductor wafer that extends beyond a depth of the circuitry and forms an edge of the die;
placing a passivation layer on the edge; and
removing a back surface of the semiconductor wafer to intersect the trench such that the dies are separated from the semiconductor wafer.

2. The method recited in claim 1, wherein a scribe seal is not present in the die and the circuitry terminates at the scribe street.

3. The method recited in claim 1, wherein a width to depth aspect ratio of the trench ranges from about 1:8 to about 1:10.

4. The method recited in claim 1 wherein etching includes using a wet etch, a plasma etch or a laser.

5. The method recited in claim 1, wherein the passivation layer comprises silicon nitride, silicon oxygen nitride, or combinations thereof.

6. The method recited in claim 1 wherein the passivation layer is an outermost passivation layer and the method includes depositing an overcoat layer over the semiconductor wafer prior to placing the outermost passivation layer on the edge.

7. The method recited in claim 1 wherein a portion of the scribe street remains between the passivation layer and the circuitry subsequent to removing.

8. The method recited in claim 1 wherein removing includes removing the back side of the semiconductor wafer with a chemical/mechanical polishing process.

9. A method of manufacturing a semiconductor device, comprising:
forming active circuitry within dies located on a semiconductor wafer, a scribe street being located between each of the dies and wherein the active circuitry terminates at the scribe street;
etching a trench into each of the scribe streets to a depth that extends beyond a depth of the active circuitry, wherein a portion of the scribe street remains between the trench and the active circuitry subsequent to the etching to form an edge of the die and a scribe seal is not present between the edge of the die and the active circuitry;
placing a passivation layer on the edge of the die such that the passivation layer extends past the depth of the active circuitry; and
removing a back surface of the semiconductor wafer to intersect the trench such that the dies are separated from the semiconductor wafer and the passivation layer remains on the edge of the die.

10. The method recited in claim 9, wherein a width to depth aspect ratio of the trench ranges from about 1:8 to about 1:10.

11. The method recited in claim 10 wherein forming includes using a wet etch, a plasma etch, or a laser.

12. The method recited in claim 9, wherein the passivation layer comprises silicon nitride, silicon oxygen nitride, or combinations thereof.

13. The method recited in claim 9 wherein the passivation layer is an outermost passivation layer and the method includes depositing an overcoat layer over the semiconductor wafer prior to placing the outermost passivation layer on the walls, the passivation layer overlapping a portion of the overcoat layer such that the passivation layer and the overcoat layer form a seal for the semiconductor device.

14. The method recited in claim 9 wherein the passivation layer forms a seal over the active circuitry.

15. The method recited in claim 9 wherein the semiconductor device is an integrated circuit and forming active circuitry includes forming transistors that includes gates and source/drains and the method further includes forming dielectric layers over the gates, and forming interconnects over and within the dielectric layers to interconnect the gates and source/drains.

16. A semiconductor device, comprising:
a die having an etched edge that includes a portion of a scribe street;
active circuitry located on the die;
dielectric layers located over the active circuitry;
interconnects located within and over the dielectric layers that contact the active circuitry, the active circuitry, dielectric layers and interconnects forming at least a portion of an integrated circuit (IC), wherein the IC terminates at the edge of the die; and
a passivation layer located on the portion of the scribe street, wherein a scribe seal is not present between the edge of the die and the active circuitry.

17. The device recited in claim 16, wherein the die comprises silicon and the portion of the scribe street includes silicon.

18. The device recited in claim 16, wherein the passivation layer is an outermost passivation layer and the device further includes an overcoat layer located under the outermost passivation layer.

19. The device recited in claim 18, wherein the overcoat layer does not extend onto the edge of the die.

20. The device recited in claim 16, wherein the passivation layer overlaps a portion of the overcoat layer and the portion that is overlapped is adjacent the edge, the passivation layer and overcoat layer forming a seal for the semiconductor device.
